(19) United States
(12) Patent Application Publication
(10) Pub. No.: US 2009/0140823 A1
(43) Pub. Date: Jun. 4, 2009

(54) BROADBAND MICROSTRIP BALUN AND METHOD OF MANUFACTURING THE SAME

(75) Inventors: Dong-hyun Lee, Anyang-si (KR); Jung-han Choi, Hwaseong-si (KR); Young-hwan Kim, Hwaseong-si (KR); Chul-soo Kim, Hwaseong-si (KR); Sung-tae Choi, Hwaseong-si (KR); Cheol-gyu Hwang, Suwon-si (KR)

Correspondence Address: SUGHRUE MION, PLLC, 2100 PENNSYLVANIA AVENUE, N.W., SUITE 800, WASHINGTON, DC, 20037, US

(73) Assignee: Samsung Electronics Co., Ltd., Suwon-si (KR)

(21) Appl. No.: 12/058,781

(22) Filed: Mar. 31, 2008

(30) Foreign Application Priority Data
Nov. 30, 2007 (KR) 10-2007-0123858

(51) Int. Cl. H01P 5/10; H03H 3/00

(52) U.S. Cl. 333/26; 29/825

(57) ABSTRACT

A broadband microstrip balun and a method of manufacturing the same are provided. In the balun, transmission lines formed at different layers partially overlap in parallel with each other, and a common ground having a predetermined opening is inserted between the transmission lines. Thus, an unbalanced signal may be converted into a balanced signal in a broad frequency band using resonance of a common ground plate with the opening and a Bethe hall effect. Also, impedance matching is readily enabled, thereby reducing a parasitic element.

### CROSS REFERENCE TO RELATED APPLICATIONS

This application claims priority from Korean Patent Application No. 10-2007-0123858, filed on Nov. 30, 2007, the disclosure of which is incorporated herein in its entirety by reference.

### BACKGROUND OF THE INVENTION

1. Field of the Invention

The present invention relates to a balance-to-unbalance (balun) for matching an unbalanced signal with a balanced signal, and more particularly, to a broadband microstrip balun and a method of manufacturing the same that are capable of reducing signal loss and conversion errors in a broad frequency band using a microstrip structure.

2. Description of the Related Art

In a microwave circuit, such as a communication circuit, a balun is a critical passive device that matches an unbalanced signal with a balanced signal. Such a balun is generally used at connections of a balanced mixer, a balanced amplifier, a phase shifter, a frequency discriminator, an antenna, and a low-noise amplifier of blocks of radio-frequency (RF) transmitting/receiving units in mobile communication systems.

A conventional balun includes an unbalanced circuit in which one of a pair of terminals is grounded and a balanced circuit in which a pair of terminals are not grounded and connected to another circuit. When an ideal balun is used, balanced signals having half the intensity of an input signal and a phase difference of 180° therebetween may be output from an output terminal of the balanced circuit.

Various types of baluns, for example, a coaxial balun, a Marchand balun, a slot-coupled balun, a lumped-element balun, have been proposed and applied to circuits. In particular, it is known that a coaxial balun has excellent matching characteristics in a broad frequency band. However, it is difficult to apply the coaxial balun to ordinary circuits and also, due to its structural properties, practically manufacture an open coaxial stub of the coaxial balun.

In contrast, a balun using a planar transmission line (a planar balun) may be easily applied to ordinary circuits and manufactured using a comparatively simple process. However, the planar balun has a narrower bandwidth than the coaxial balun. Among planar baluns, a microstrip-to-slotline transition balun has excellent matching characteristics, but it has no common ground. Thus, it is difficult to apply the microstrip-to-slotline transition balun to circuits requiring common grounds.

### SUMMARY OF THE INVENTION

The present invention provides a broadband microstrip balun having excellent matching characteristics, in which a common ground is disposed between two balanced output terminals, and a method of manufacturing the same.

The broadband microstrip balun includes microstrip transmission lines formed at different layers and a common ground plate with an opening disposed between the microstrip transmission lines.

Additional aspects of the invention will be set forth in the description which follows, and in part will be apparent from the description, or may be learned by practice of the invention.

The present invention discloses a broadband microstrip balun, including: a first strip line disposed on an upper substrate and having an input port, to which a signal is input, at one end portion thereof; a second strip line disposed on a lower substrate and having output ports at both end portions thereof, a portion of the second strip line overlapping in parallel with the first strip line; and a common ground plate disposed between the upper substrate and the lower substrate and having an opening formed by partially opening an overlapping portion between the first and second strip lines.

The opening may shift a phase of a signal passing through the first strip line and transmit the phase-shifted signal to the second strip line. The opening may have a rectangular or dumbbell shape.

The other end portion of the first strip line may be an open circuit.

A length between a point of the first strip line corresponding to the center of the opening and the other end portion of the first strip line may be ¼ of the wavelength of the signal input to the input port.

A characteristic impedance of the input port may be matched with a characteristic impedance of each of the output ports by controlling a width of the first strip line or a width of the second strip line.

The width of the second strip line may be greater than the width of the first strip line.

An unbalanced signal may be input to the input port of the first strip line, and balanced signals may be output from the output ports of the second strip line. In this case, the balanced signals may have ½ the intensity of the unbalanced signal and a phase difference of 180+ therebetween.

In another aspect of the present invention, balanced signals may be input to the output ports of the second strip line, and an unbalanced signal may be output from the input port of the first strip line.

The present invention also discloses a method of manufacturing a balun having an unbalanced line and a balanced line, including: forming a first layer having the unbalanced line; forming a second layer having the balanced line partially overlapping in parallel with the unbalanced line; and forming a common ground layer between the first and second layers such that an overlapping portion between the unbalanced line and the balanced line is partially opened.

Each of the first and second layers and the common ground layer may be formed by a semiconductor manufacturing process, a multilayered printed circuit board (PCB) process, or a low-temperature co-fired ceramic (LTCC) process.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiments of the invention, and together with the description serve to explain the aspects of the invention.

FIG. 1 is an exploded perspective view of a broadband microstrip balun according to an exemplary embodiment of the present invention.

FIG. 2 is an exploded plan view of the broadband microstrip balun shown in FIG. 1.

FIGS. 3 and 4 are diagrams illustrating the operating principles of a broadband microstrip balun according to an exemplary embodiment of the present invention.

FIG. 5 is a flowchart illustrating a method of manufacturing a broadband microstrip balun according to an exemplary embodiment of the present invention.

FIG. 6 is cross-sectional views illustrating a method of manufacturing a broadband microstrip balun according to an exemplary embodiment of the present invention.

### DETAILED DESCRIPTION OF EXEMPLARY EMBODIMENTS

The invention is described more fully hereinafter with reference to the accompanying drawings, in which exemplary embodiments of the invention are shown. This invention may, however, be embodied in many different forms and should not be construed as limited to the exemplary embodiments set forth herein. Rather, these exemplary embodiments are provided SO that this disclosure is thorough, and will fully convey the scope of the invention to those skilled in the art. In the drawings, the size and relative sizes of layers and regions may be exaggerated for clarity. Like reference numerals in the drawings denote like elements.

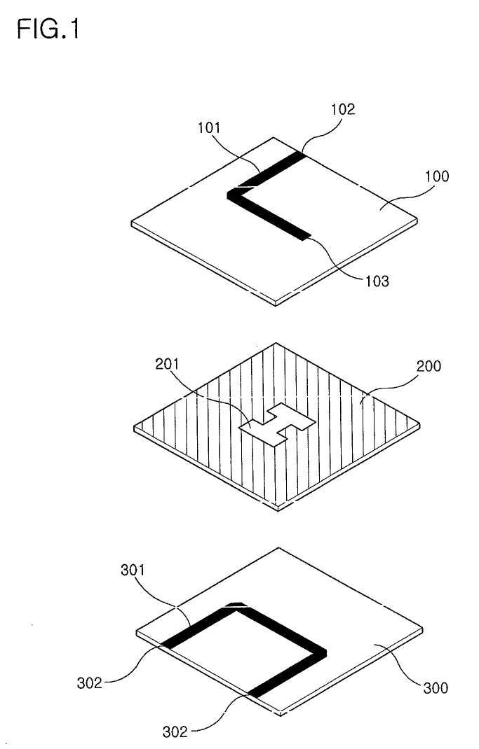

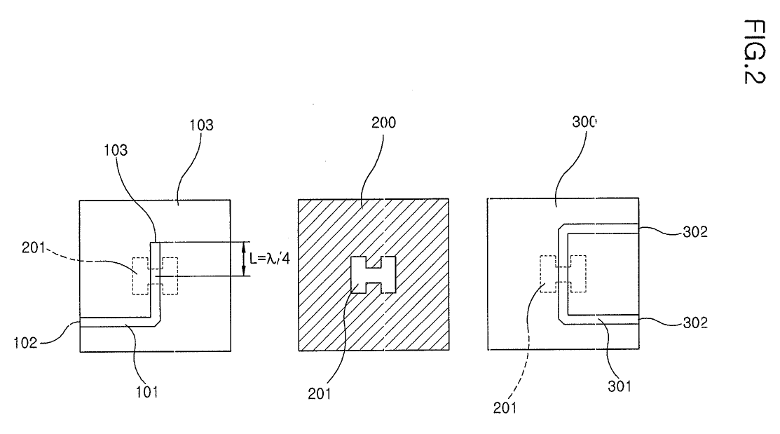

FIG. 1 is an exploded perspective view of a broadband microstrip balun according to an exemplary embodiment of the present invention. As shown in FIG. 1, the broadband microstrip balun may be largely divided into three layers, and FIG. 2 is an exploded plan view of each of the three layers of the broadband microstrip balun shown in FIG. 1.

Referring to FIGS. 1 and 2, the broadband microstrip balun according to an exemplary embodiment of the present invention includes a first strip line 101, a second strip line 301, and a common ground plate 200 having an opening 201.

The first strip line 101 is a transmission line disposed on an upper substrate 100, and an unbalanced signal flows through the first strip line 101. An input port 102 to which a signal is input is disposed at one end portion of the first strip line 101, and an open circuit 103 is disposed at the other end portion thereof That is, the other end portion of the first strip line 101 is open.

The first strip line 101 may be formed by depositing or printing a metal line, for example, a copper line or an aluminum line, on a predetermined dielectric block or a dielectric substrate. As shown in FIGS. 1 and 2, the first strip line 101 may be bent toward the center of the upper substrate 100 from the input port 102.

The second strip line 301 is a transmission line disposed on a lower substrate 300. The unbalanced signal applied to the first strip line 101 is converted into a balanced signal, and the balanced signal flows through the second strip line 301. Also, output ports 302 are disposed at both end portions of the second strip line 301.

Like the first strip line 101, the second strip line 301 may be formed by depositing or printing a metal line, for example, a copper line or an aluminum line, on a predetermined dielectric block or a dielectric substrate.

Also, a portion of the second strip line 301 overlaps in parallel with the first strip line 101. Since the first and second strip lines 101 and 301 are formed on the upper and lower substrates 100 and 300, respectively, the first and second strip lines 101 and 301 are formed at different layers. Accordingly, when the portion of the second strip line 301 overlaps in parallel with the first strip line 101, the first and second strip lines 101 and 301 are located on predetermined parallel planes, respectively. In other words, as shown in FIG. 1, the second strip line 301 may be aligned underneath the first strip line 101 such that the first strip line 101 overlaps the second strip line 301. The first and second strip lines 101 and 301 may wholly overlap in parallel with each other. Portions of the first and second strip lines 101 and 301 except the input port 101 and the output ports 302 may overlap in parallel with each other.

For example, as shown in FIG. 2, the first strip line 101 may extend inward from the input port 102 and bend and extend in a “┐” or “L” shape once toward the center of the upper substrate 100. The second strip line 301 may partially overlap in parallel with a bent portion of the first strip line 101, and both end portions of the second strip line 301 extend in an opposite direction to the input port 102, so that the entire second strip line 301 forms a “∩” shape.

The common ground plate 200 is a ground plate interposed between the upper substrate 100 and the lower substrate 300 and functions as a common ground for both the first and second strip lines 101 and 301. Thus, when an electric signal is applied, an electric field is formed between each of the first and second strip lines 101 and 301 and the common ground plate 200. The common ground plate 200 may be a metal plate formed of the same material as the first and second strip lines 101 and 301.

Also, the common ground plate 200 has a predetermined opening 201. The opening 201 is obtained by partially opening an overlapping portion between the first and second strip lines 101 and 301. The opening 201 shifts the phase of a signal passing through the first strip line 101 and transmits the phase-shifted signal to the second strip line 301. In this case, the opening 201 may be formed as a rectangular or dumbbell shape, but the present invention is not limited thereto. Referring to FIG. 2, the overlapping portion between the first and second strip lines 101 and 301 and the opening 201 of the common ground plate 200 may be structurally disposed in the center.

Accordingly, an unbalanced signal input to the input port 102 is applied through the first strip line 101, transmitted to the second strip line 301 via the opening 201, converted into a balanced signal, and output to each of the output ports 302. In this case, two balanced signals output via the output ports 302 of the second strip line 301 have half the intensity of the unbalanced signal and a phase difference of 180° therebetween.

In the present exemplary embodiment, it is described that the first strip line 101 is formed on the upper substrate 100 and the second strip line 301 is formed on the lower substrate 300, but the present invention is not limited thereto. In another exemplary embodiment, the second strip line 301 may be formed on the upper substrate 100 and the first strip line 101 may be formed on the lower substrate 300.

Also, it is possible that a balanced signal is input to the output ports 302 of the second strip line 301 and transmitted to the first strip line 101 by the opening 201, and an unbalanced signal is output via the input port 102 of the first strip line 101.

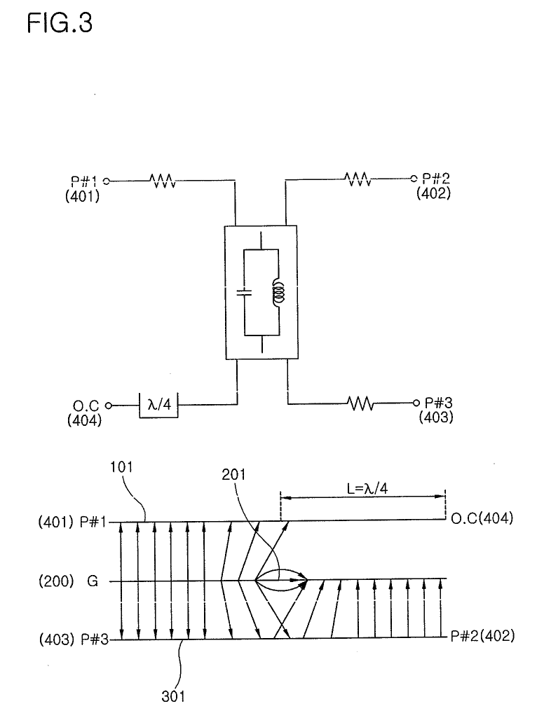

The operating principles of the broadband microstrip balun shown in FIGS. 1 and 2, according to the exemplary embodiment of the present invention will now be described with reference to FIG. 3.

Specifically, FIG. 3 illustrates a cross-section of the overlapping portion between the first and second strip lines 101 and 301 and a distribution of an electric field of the overlapping portion.

Referring to FIG. 3, it is set that a length L between a point of the first strip line 101 corresponding to the center of the opening 201 and the other end portion of the first strip line 101 is ¼ of the wavelength λ of an input signal. Thus, the one end portion of the first strip line 101 may correspond to a first port 401 to which the input signal is input, and the other end portion thereof may correspond to an open circuit 404.

A second port 402 and a third port 403 are prepared at both end portions of the second strip line 301 so that a signal input to the first port 401 is output via the second and third ports 402 and 403.

As described above, the common ground plate 200 is formed between the first and second strip lines 101 and 301 and has the predetermined opening 201. Here, the opening 201 may conceptually correspond to a resonance circuit. That is, similarly to a defected ground structure (DGS), the common ground plate 200 makes a reverse use of resonance caused by attenuation of frequencies in a specific range and allows conversion of a balanced signal into an unbalanced signal.

When an electric signal is input to the first port 401, a predetermined electric field is generated as shown in FIG. 3. Here, it is assumed that the common ground plate 200 is a relative minus (−) as illustrated with a tail of an arrow and each of the first and second strip lines 101 and 301 is a relative plus (+) as illustrated with a head of the arrow.

Since each of the first and second strip lines 101 and 301 corresponds parallel to the common ground plate 200, the electric field is generated vertically between each of the first and second strip lines 101 and 301 and the common ground plate 200. However, due to the opening 201 included in the common ground plate 200, the electric field is slightly bent near the opening 201. Especially, the direction of the electric field is shifted centering on the opening 201 due to a Bethe hall effect. On comparing an electric field generated near the second port 402 with an electric field formed near the third port 403, it can be seen that the electric field formed near the second port 402 is generated in an opposite direction to the electric field formed near the third port 403. Thus, an output signal output via the second port 402 may have an inverted phase to an output signal output via the third port 403. Although not shown in the drawings, an electric field is generated near the open circuit 404 as near the second port 402.

As a result, an unbalanced signal is input to the first port 401 and converted into balanced signals with inverted phases so that the balanced signals with the inverted phases are output via the second and third ports 402 and 403.

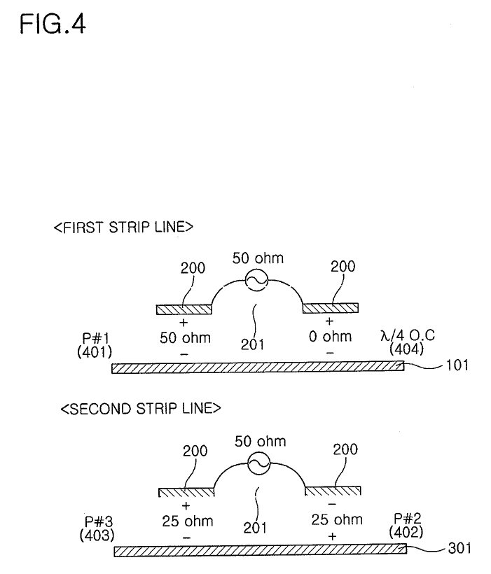

Also, the broadband microstrip balun according to the present exemplary embodiment may easily match a characteristic impedance of an input port (i.e., the first port 401) with a characteristic impedance of output ports (i.e., the second and third ports 402 and 403) by controlling the width of each of the first and second strip lines 101 and 301, as will be described in detail with reference to FIG. 4.

In FIG. 4, it is assumed that the width of the second strip line 301 is greater than that of the first strip line 101. On the basis of the opening 201, the first port 401 of the first strip line 101 has an impedance of 50 Ω, and the other side, i.e., the open circuit 404 of the first strip line 101 has an impedance of 0 Ω. Accordingly, an input port of the first strip line 101 has a characteristic impedance of 50 Ω. Since the second strip line 301 has a greater width than the first strip line 101, each of the second and third ports 402 and 403 of the second strip line 301 has an impedance of 25 Ω on the basis of the opening 201. In this case, the impedance of each of the second and third ports 402 and 403 may be set on the basis of the opening 201 by appropriately controlling the width of the second strip line 301. Also, as described above, an electric field formed near the second port 402 is generated in an opposite direction to an electric field formed near the third port 403. Thus, an output port of the second strip line 301 generally has a characteristic impedance of 50 Ω. As described above, it is possible to match the characteristic impedance of the input port with the characteristic impedance of the output ports by appropriately controlling the width of the first strip line 101 or the width of the second strip line 301.

In the above-described construction, the common ground plate 200 is formed between the first and second strip lines 101 and 301 and a signal is transmitted through the opening 201 formed in the common ground plate 200. Thus, no additional device for transmitting signals is required. Accordingly, a parasitic element caused by the additional device may be reduced, and a balanced signal may be converted into an unbalanced signal in a broad frequency band. Furthermore, characteristic impedances of input and output ports may be matched with each other by controlling the width of each of the first and second strip lines 101 and 301.

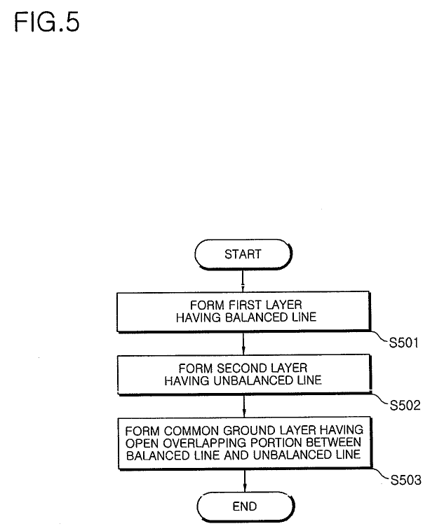

Hereinafter, a method of manufacturing a broadband microstrip band according to an exemplary embodiment of the present invention will be described with reference to FIG. 5.

Referring to FIG. 5, a method of manufacturing a broadband microstrip band including a balanced line and an unbalanced line includes forming a first layer having the unbalanced line (S501), forming a second layer having the balanced line (S502), and forming a common ground layer between the first and second layers (S503).

In operation S502, the balanced line partially overlaps in parallel with the unbalanced line. In operation S503, an overlapping portion between the balanced line and the unbalanced line is partially opened. Also, the unbalanced line of the first layer may be formed such that a length between a point of the unbalanced line corresponding to the open portion of the common ground layer and one end portion of the unbalanced line is ¼ of the wavelength of an input signal. Furthermore, the width of the balanced line may be greater than that of the unbalanced line.

In this case, the first layer, the second layer, and the common ground layer may be sequentially formed by a semiconductor manufacturing process. Alternatively, the first and second layers and the common ground layer may be separately formed by a low-temperature co-fired ceramic (LTCC) process or a printed circuit board (PCB) process. However, the present invention is not limited thereto.

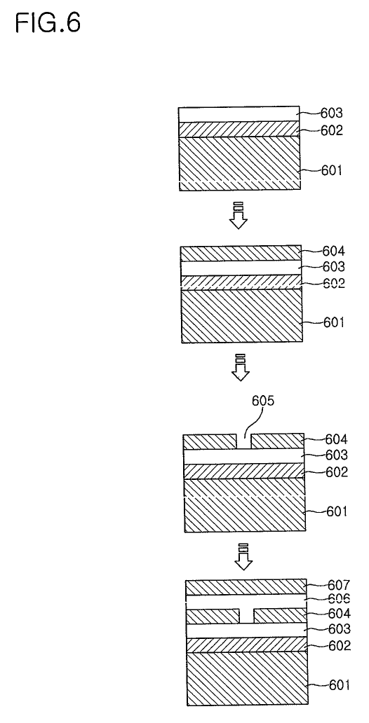

As an example, a method of stacking the first and second layers and the common ground layer using a semiconductor manufacturing process will be described with reference to FIG. 6.

Referring to FIG. 6, a first metal layer 602 is deposited on a main substrate 601 and a first dielectric layer 603 is coated thereon. Before coating the first dielectric layer 603, an appropriate line pattern may be formed by etching the first metal layer 602 to be used as the second strip line 301.

Next, a common ground layer 604 is formed on the first dielectric layer 603. The common ground layer 604 may be formed of the same material as the first metal layer 602 such that a predetermined electric field is generated between the first metal layer 602 and the common ground layer 604.

Thereafter, the common ground layer 604 is partially etched to form an opening 605. The opening 605 may be formed in a rectangular or dumbbell shape using a mask with a predetermined pattern.

Thereafter, a second dielectric layer 606 is coated on the opening 605 and the common ground layer 604, and a second metal layer 607 is deposited on the second dielectric layer 606. A predetermined pattern may be formed by etching the second metal layer 607 to be used as the first strip line 101.

As described above, a signal flowing through the second metal layer 607 should be transmitted to the first metal layer 602 via the opening 605. Therefore, the second metal layer 607, the opening 605, and the first metal layer 602 are overlapped or aligned in parallel with one another.

As apparent from the above description, an unbalanced transmission line is signally connected to a balanced transmission line via a predetermined opening so that an unnecessary parasitic element can be reduced. Also, since a broadband microstrip balun according to the present invention makes use of resonance of a common ground plate with the opening and a Bethe hall effect, an unbalanced signal can be converted into a balanced signal in a broad frequency band. Above all, since impedance matching is enabled by controlling the width of each of the unbalanced transmission line and the balanced transmission line without using an additional device, it can be applied to a broadband receiving terminal requiring differential signal processing, thereby minimizing common-mode noise. Furthermore, the broadband microstrip balun can be manufactured using a multilayered metal manufacturing process, it can be applied to microwave integrated circuits (ICs).

It will be apparent to those skilled in the art that various modifications and variations can be made in the present invention without departing from the spirit or scope of the invention. Thus, it is intended that the present invention covers the modifications and variations of this invention provided they come within the scope of the appended claims and their equivalents.

What is claimed is:

1. A broadband microstrip balun comprising:
a first strip line disposed on an upper substrate and having an input port, to which a signal is input, at one end portion thereof;
a second strip line disposed on a lower substrate and having output ports at both end portions thereof, a portion of the second strip line overlapping in parallel with the first strip line; and
a common ground plate disposed between the upper substrate and the lower substrate and having an opening formed by partially opening an overlapping portion between the first and second strip lines.

2. The broadband microstrip balun of claim 1, wherein the opening shifts a phase of a signal passing through the first strip line and transmits the phase-shifted signal to the second strip line.

3. The broadband microstrip balun of claim 1, wherein the other end portion of the first strip line is an open circuit.

4. The broadband microstrip balun of claim 1, wherein a length between a point of the first strip line corresponding to the center of the opening and the other end portion of the first strip line is ¼ of the wavelength of the signal input to the input port.

5. The broadband microstrip balun of claim 1, wherein a characteristic impedance of the input port is matched with a characteristic impedance of each of the output ports by controlling a width of the first strip line or a width of the second strip line.

6. The broadband microstrip balun of claim 1, wherein a width of the second strip line is greater than a width of the first strip line.

7. The broadband microstrip balun of claim 1, wherein the opening has a rectangular shape or a dumbbell shape.

8. The broadband microstrip balun of claim 1, wherein each of the upper and lower substrates is a dielectric block or a dielectric substrate.

9. The broadband microstrip balun of claim 1, wherein an unbalanced signal is input to the input port of the first strip line, and balanced signals are output from the output ports of the second strip line,
wherein the balanced signals have ½ the intensity of the unbalanced signal and a phase difference of 180° therebetween.

10. A broadband microstrip balun comprising:
a first strip line disposed on a first substrate;
a second strip line disposed on a second substrate and partially overlapping in parallel with the first strip line; and
a common ground plate disposed between the first and second substrates and having an opening formed by partially opening an overlapping portion between the first and second strip lines.

11. The broadband microstrip balun of claim 10, wherein the opening shifts a phase of a signal passing through the first strip line to transmit the phase-shifted signal to the second strip line or shifts a phase of a signal passing through the second strip line to transmit the phase-shifted signal to the first strip line.

12. The broadband microstrip balun of claim 10, wherein an unbalanced signal is input to an end portion of the first strip line, and balanced signals are output from both end portions of the second strip line.

13. The broadband microstrip balun of claim 10, wherein balanced signals are input to both end portions of the second strip line, and an unbalanced signal is output from an end portion of the first strip line.

14. A method of manufacturing a balun having an unbalanced line and a balanced line, comprising:
forming a first layer having the unbalanced line;
forming a second layer having the balanced line partially overlapping in parallel with the unbalanced line; and
forming a common ground layer between the first and second layers such that an overlapping portion between the unbalanced line and the balanced line is partially opened.

15. The method of claim 14, wherein each of the first and second layers and the common ground layer is formed by a semiconductor manufacturing process, a multilayered printed circuit board (PCB) process, or a low-temperature co-fired ceramic (LTCC) process.

16. The method of claim 14, wherein a length between a point of the unbalanced line corresponding to the center of an open portion of the common ground layer and an end portion of the unbalanced line is ¼ of the wavelength of an input signal.

17. The method of claim 14, wherein a width of the balanced line is greater than a width of the unbalanced line.

18. The method of claim 14, wherein an open portion of the common ground layer has a rectangular shape or a dumbbell shape.
